(19) United States
(12) Patent Application Publication
(10) Pub. No.: US 2025/0075327 A1
(43) Pub. Date: Mar. 6, 2025

(54) Method of the Thermal Processing of Metallurgy Parts

(71) Applicant: TAT Technology, Saint Marys, PA (US)

(72) Inventor: Harbhajan Nayar, Murray Hill, NJ (US)

(21) Appl. No.: 18/738,898

(22) Filed: Jun. 10, 2024

Related U.S. Application Data
(63) Continuation of application No. 18/454,350, filed on Aug. 23, 2023.

(51) Int. Cl. C23C 16/54; C23C 16/52

(52) U.S. Cl. CPC C23C 16/54; C23C 16/52

(57) ABSTRACT

A thermal processing apparatus comprises a reaction zone having a first and second opening, a conveyor system that transports a desired material from the first opening to the second opening, an exhaust system communicatively connected to the first opening, and a plenum positioned above the reaction zone that extends from about the first opening to about the second opening. A vented barrier between the plenum and the reaction zone comprises a plurality of vents arranged such that the density of vents is highest near the first opening and progressively lower toward the second opening. A gas supply and a gas heater are communicatively connected to the plenum to introduce and condition an atmosphere to the plenum that is released into the reaction zone through the vents.

### BACKGROUND OF THE INVENTION

Powder metallurgy has become an increasingly attractive option for metals processing in recent years due to its reduced cost and lower material losses as compared to other formation methods like melt-based processes. Powder metallurgy refers, generally, to a variety of processes by which metal powders are pressed into a desired shape and then sintered to bond particles together and achieve the desired properties of the final metal part.

Powder metallurgy processes generally begin with a step to create the constituent metal powder. There are many ways to form metal and metal alloy powders with different particle shapes, sizes, and properties. These methods often include crushing, grinding, chemical reactions, or electrolytic deposition. Another very popular method to produce metal powders is via water or gas atomization. Whereby, a molten liquid metal stream is exposed to compressed water from a nozzle to break up the molten metal stream into fine droplets that when cooled solidify into a fine powder.

The second step in powder metallurgy processes is often referred to as particle shaping or powder compaction. Powdered metal materials are generally admixed with organic lubricants and/or various binders to help maintain a desired shape and particle structure prior to sintering. The powder/lubricant mixture is then formed into its desired shape by one of many methods, including pressing, metal injection molding, additive manufacturing, or other comparable methods. At this stage, the part is called a “green” part. It is strong enough to be physically handled but not strong enough to sustain a load.

The final step in powder metallurgy processes is a sintering cycle. Methods for sintering vary widely within metallurgical industries. Generally, sintering cycles involve exposing the shaped “green” part to an atmosphere of controlled conditions and chemical composition to gradually increase the temperature of the part, remove lubricants, and initiate the bonding of the powdered particles to create the desired properties of the resulting sintered metal part. However, traditional systems and methods used in sintering processes are inflexible, making them difficult to ensure the safe and complete decomposition of the admixed, organic lubricants and binders from the “green” part during the sintering process.

### SUMMARY OF THE INVENTION

Operators in a relevant field may require devices and methods for the thermal processing of metallurgy parts prepared with organic materials. Non-limiting embodiments discussed below concern improved systems and methods to ensure the safe, efficient, and complete decomposition and vaporization of admixed, organic lubricants and binders from metallurgy parts.

Some non-limiting embodiments of the device and methods disclosed herein may facilitate the heating of a metallurgy part or parts as they are transported through a reaction zone of the device. The apparatus may supply and condition gas through a plurality of vents, distributed across the length of the apparatus in a pre-determined arrangement within a vented barrier positioned above the reaction zone, to the reaction zone to create a controlled atmosphere with a known flow, temperature, pressure, and chemical composition to interact with metallurgy parts and facilitate the removal of undesired materials by fully oxidizing organic-based lubricants and binders that are normally admixed or coated on to “green” parts or other metallurgy parts prior to sintering. The arrangement of vents may be such that the density of the vents is highest near the opening where the metallurgy parts are introduced into the apparatus and lowest near the opening where metallurgy parts exit the apparatus.

In another aspect, the device and methods may incorporate an apparatus with a modular design. The modular design may feature modules, each capable of supplying a conditioned atmosphere to its own reaction zone, that make up the apparatus. Transporting metallurgy parts through the interconnected reaction zones of the multiple modules may allow an operator to more effectively control the reaction conditions within specific areas of the reaction zones of the multiple modules to facilitate the efficient and particularized removal of organic-based lubricants and binders from “green” parts or other metallurgy parts.

In another aspect, the device and methods may utilize an apparatus that may be communicatively connected or retrofitted to an existing thermal processing furnace. The apparatus may accept an incoming atmosphere into the reaction zone or reaction zones that originates from the thermal processing furnace or some other source. This incoming atmosphere may contain combustibles and may mix with the conditioned atmosphere inside the reaction zone or zones.

In another aspect, some embodiments discussed herein concern a device and methods for the removal of organic-based lubricants and binders from “green” parts or other metallurgy parts that render the resulting atmosphere free of hydrocarbons and other harmful vapors. This treated atmosphere may then be vented through an exhaust system communicatively connected to the reaction zone.

This Summary is provided to introduce a selection of concepts in a simplified form that is further described below in the Detailed Description. This Summary is not intended to identify key features or essential features of the claimed subject matter, nor is it intended to be used to limit the scope of the claimed subject matter. Furthermore, the claimed subject matter is not limited to limitations that solve any or all disadvantages noted in any part of this disclosure.

### BRIEF DESCRIPTION OF THE DRAWINGS

The novel features of the invention are set forth with particularity in the appended claims. A better understanding of the features and advantages of the present invention will be obtained by reference to the following detailed description that sets forth illustrative embodiments, in which the principles of the invention are utilized, and the accompanying drawings of which:

FIG. 1 illustrates an embodiment of the thermal processing apparatus in a single-module configuration.

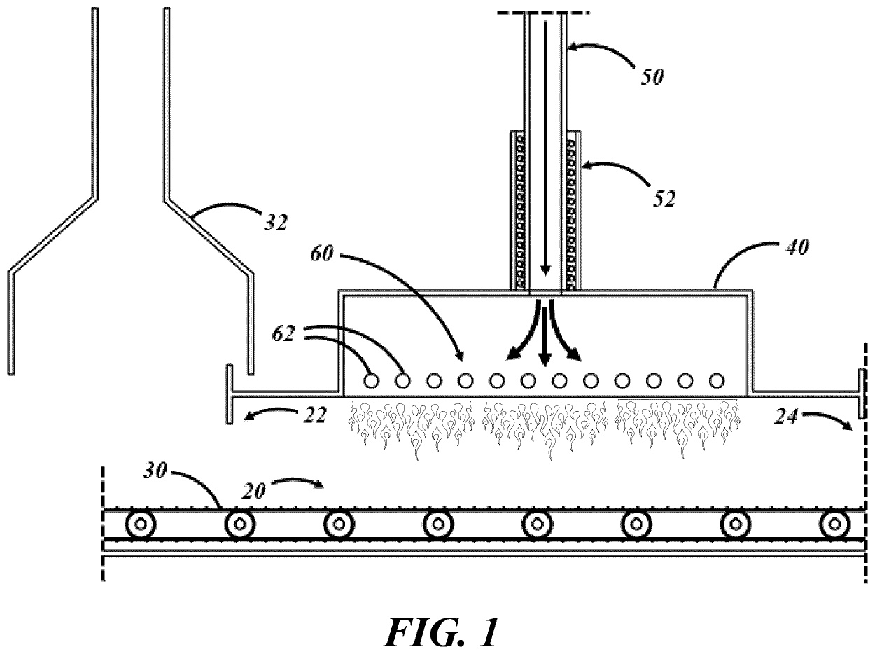

FIG. 2 illustrates an embodiment depicting the flow of gas through the thermal processing apparatus in a single-module configuration.

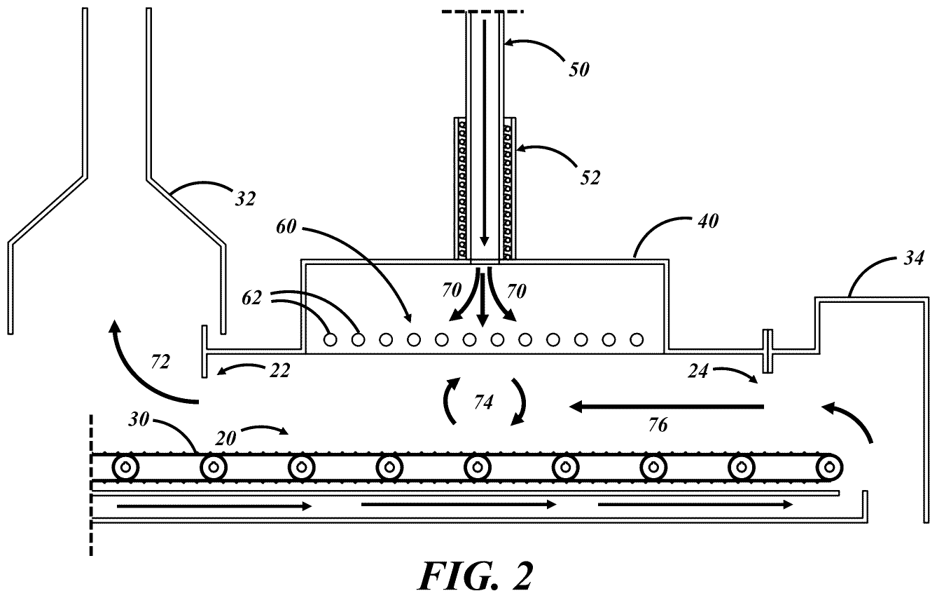

FIG. 3 illustrates a close-up depiction of the vented barrier and the arrangement of vents therein.

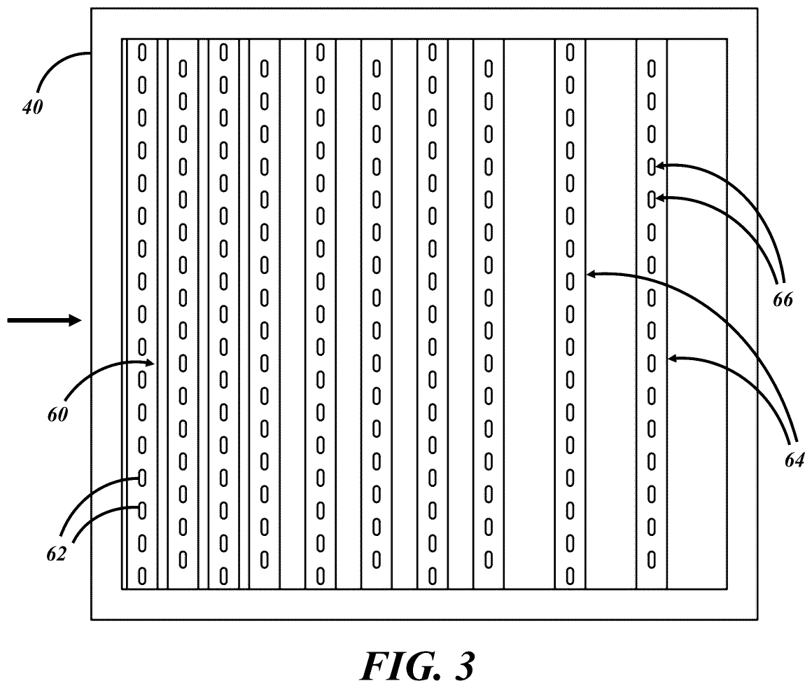

FIG. 4 illustrates an embodiment of the thermal processing apparatus in a multi-module configuration.

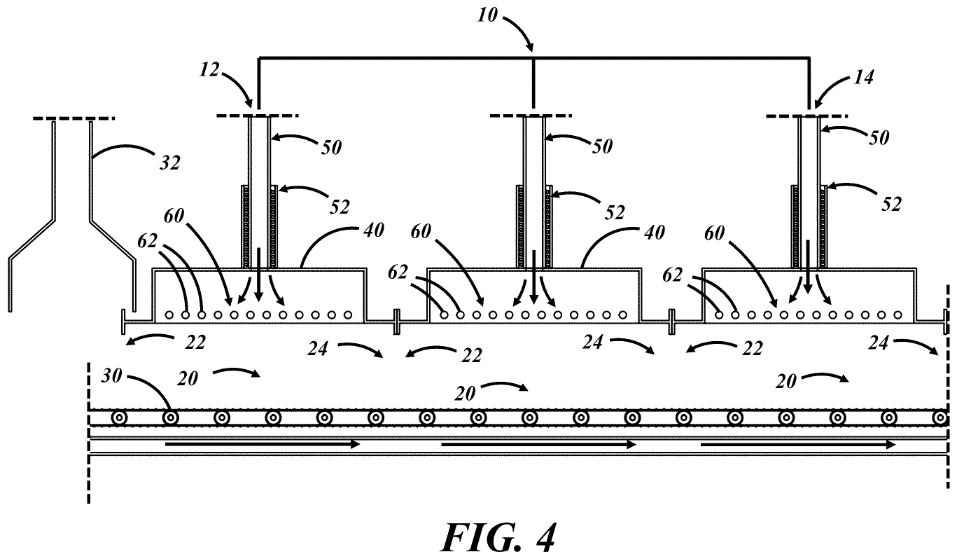

FIG. 5 illustrates an embodiment depicting the flow of gas through the thermal processing apparatus in a multi-module configuration.

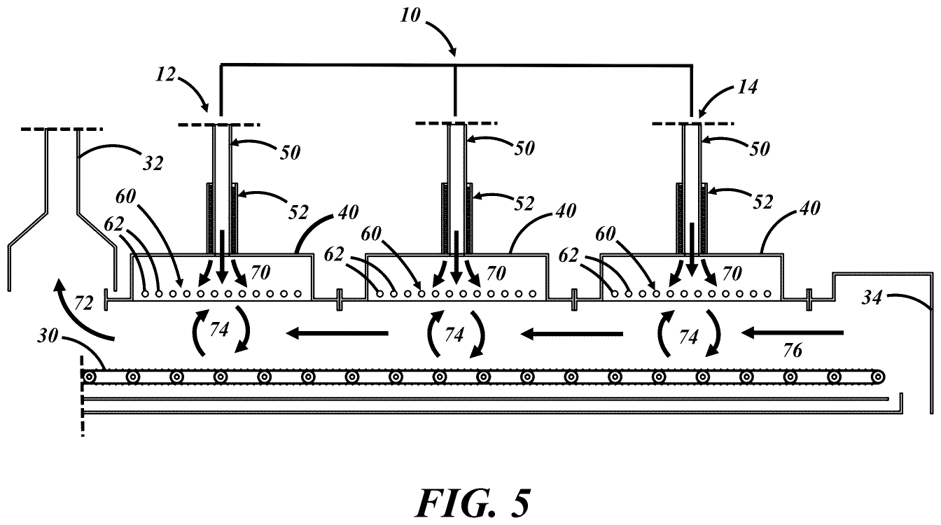

### DETAILED DESCRIPTION OF THE INVENTION

What is presented are improved systems and methods to ensure the safe and complete decomposition and vaporization of admixed, organic lubricants and binders from “green” parts during the sintering process. Aspects disclosed herein describe a thermal processing apparatus for thermally removing and safely decomposing organic materials admixed with metallic powdered materials. In some embodiments, the apparatus may comprise the following subparts: a reaction zone 20 having a first 22 and second opening 24, a conveyor system 30, an exhaust system 32, a plenum 40, a gas supply 50, a gas heater 52, and a vented barrier 60 comprising a plurality of vents 62.

In the embodiments discussed herein, the thermal processing apparatus has a length extending in the direction from the first opening 22 to the second opening 24, a height extending upward from the conveyor system 30, and a width extending across the apparatus.

In some embodiments, the reaction zone 20 forms the primary chamber of the thermal processing apparatus in which metallurgy parts will pass through to achieve melting, vaporizing, removing, and oxidizing of the organic binders and lubricants. The reaction zone may have a first opening 22 and a second opening 24 positioned at opposite sides of the reaction zone so that a “green” part may be introduced into the reaction zone through the first opening, where it may progress through the reaction zone at a determined rate and exit the reaction zone through the second opening. The exterior of the apparatus around the first and second openings may further include flanges, or other equivalent means of connection known to those of ordinary skill, so that the reaction zone may be communicatively connected to some other chamber, instrument, or apparatus. In some embodiments, the reaction zone may be communicatively connected to an existing thermal processing furnace to augment or retrofit the capabilities of an existing instrument. The size of the openings may be adjusted to accommodate the introduction of parts of various sizes and to allow for the control of an incoming or outgoing atmosphere. In one embodiment, an exhaust system 32 is communicatively connected to the first opening.

Additionally, the cross-sectional area of the reaction zone will be smaller toward the second opening and larger toward the first opening to create a pressure gradient so that the atmosphere within the reaction zone will flow toward the exhaust system communicatively connected to the first opening.

In some embodiments, the thermal processing apparatus further comprises a conveyor system 30 that transports a desired material through the reaction zone from the first opening to the second opening. A conveyor system is not intended to be limited to any particular form of conveyor system and may include various types of conveyor systems or equivalent forms of movement systems that would be recognized by a person of ordinary skill in the art. The conveyor system may be one of, but is not limited to, a belt conveyor, a gravity roller conveyor, a chain conveyor, a pusher plate system, a chain driven line conveyor, or other forms of roller systems like roller hearths. The conveyor may be controlled by the user using systems known to those of ordinary skill in the art to achieve a desired movement rate or multiple movement rates.

In some embodiments, the thermal processing apparatus includes a plenum 40 positioned above the reaction zone. The plenum is a contained space having an interior chamber or duct that is suited for the conditioning of a gaseous atmosphere. The plenum may be an airtight duct with the exception of the vented barrier 60. The plenum, therefore, will contain the supplied gas as it is introduced from the gas supply 50 until the conditioned atmosphere builds in pressure and is subsequently directed through the vents 62 in the vented barrier. The plenum may extend above the reaction zone for almost the entire length of the reaction zone: from about the first opening to about the second opening. In other embodiments, the plenum extends across only a fraction of the length of the reaction zone. In one non-limiting embodiment, the plenum extends along half the length of the reaction zone. The plenum may also be positioned to extend along at least one side of the reaction zone.

In some embodiments, the plenum is communicatively connected to a gas supply 50 and a gas heater 52. In some embodiments, the gas supply may be a compressor. The gas supply may be a compressed gas tank. Additionally, the gas supply may comprise both a compressor and a gas tank. The compressed gas supply may use a regulator or other equivalent means of regulating the conditions of the supplied gas. In some embodiments, the gas supply and the gas heater may be contained within the plenum, while in other embodiments, one or both the gas supply and gas heater may be positioned outside of the plenum such that they are communicatively connected to the plenum to provide a conditioned atmosphere to the plenum's interior chamber. The gas supply and the gas heater condition and introduce an atmosphere 70 to the plenum. The gas supply, the gas heater, and the plenum may be arranged in series so that the gas is supplied from the gas supply to the gas heater, the gas heater conditions the supplied gas, and the conditioned gas is delivered to the plenum to create a conditioned atmosphere within the plenum of a controlled flow, composition, pressure, and temperature. As the conditioned atmosphere is introduced into the plenum, the pressure builds within the interior chamber of the plenum until the conditioned atmosphere is released through the plurality of vents 62 in the vented barrier and into the reaction zone.

In some embodiments, the thermal processing apparatus contains a vented barrier 60 that is positioned between the plenum and the reaction zone. In one non-limiting embodiment, the vented barrier is positioned between the plenum and the reaction zone such that the plenum is positioned above the vented barrier and the reaction zone is positioned below the vented barrier. In some embodiments, the vented barrier is made from a high-temperature plate metal. The high-temperature plate metal may be a heat resistant metal that can sustain large variations in temperature. The high-temperature plate metal may be a steel-containing alloy. However, the high-temperature plate metal may be made of any material known to those of ordinary skill that could maintain its thermal and structural properties in the high-temperature environments of this thermal processing apparatus.

In some embodiments, the vented barrier 60 comprises a plurality of vents 62. The plurality of vents may be distributed within the vented barrier so that each vent is spaced uniformly to create a uniform density of vents across the entire length of the vented barrier. In other embodiments, the plurality of vents is arranged so that the density of vents is highest near the first opening of the reaction zone and progressively lower toward the second opening. The plurality of vents may be distributed as a plurality of linear rows 64 that extends across the width of the apparatus. The number of vents that comprise each of the linear rows of vents may vary based on the rows' position within the apparatus. The plurality of rows may comprise at least four rows of vents, and each row may comprise at least six individual vents 66.

In some embodiments, each vent 66 in the plurality of the vents is an opening within the vented barrier with a rectangular cross-sectional area. The vents may all have a uniform size to control the pressure conditions of the conditioned atmosphere as it flows through each of the vents. The aspect ratio of the cross-sectional area of each vent may be at least 5. In other embodiments, the vents may have triangular, square, ovular, or circular cross-sectional areas.

In some embodiments, the gas supply 50 and the gas heater 52 may be programmed to condition the supplied gas to create a conditioned atmosphere 70 in the plenum with a desired flow, temperature, pressure, and chemical composition for thermal processing. The gas supply and the gas heater may be programmed and controlled with an external processor and external monitoring programs known to those of ordinary skill. The gas supply and the gas heater may also be programmed manually via the controls on the individual instruments. The gas supply and the gas heater may be pre-programmed to condition an atmosphere with unchanging conditions throughout the entire thermal processing cycle. Otherwise, the gas supply and the gas heater may be programmed either before or during the thermal processing cycle to produce and deliver a conditioned atmosphere with adaptive and/or changing conditions throughout the thermal processing cycle.

In some embodiments, the compressed gas supply 50 provides an oxygen-containing gas to create the conditioned atmosphere 70. The supplied gas may be an oxygen-containing gas having an oxygen content between 2 and 100 percent. The oxygen-containing gas may also be balanced with an inert gas like nitrogen. In another embodiment, the supplied gas is comprised of hydrogen. The conditioned atmosphere may also be partially comprised of nitrogen, hydrogen, carbon monoxide, methane, water vapor, carbon dioxide, and oxygen. In one non-limiting embodiment, the compressed gas supply provides air to create a conditioned atmosphere. The concentration of each of the constituent elements of the conditioned atmosphere may be highest near the first opening 22 and lowest near the second opening 24. In some embodiments, the total combined amount of oxygen entering the reaction zone of the apparatus is greater than or equal to the stoichiometric amount needed to react with and expend all the combustibles coming from an incoming atmosphere and the organic vapors generated from the admixed lubricants from the “green” parts. The gas supply may provide enough gas to the plenum 40 so that the resulting conditioned atmosphere reaches and is maintained at a predetermined pressure condition. The gas supply may provide an amount of gas to create a conditioned atmosphere within the reaction zone with adequate pressure and temperature to produce a gas flow through each of the vents 62 at a rate of 3 to 15 miles per hour. The amount of gas supplied to the plenum may be varied to create adequate flow conditions through the plurality of vents. In some embodiments, the amount of gas supplied into the thermal processing apparatus may be between 50 and 2000 SCFH. The conditioned atmosphere may be introduced to the reaction zone through the plurality of vents at a velocity sufficient to quickly mix and react with the combustibles coming from an incoming atmosphere 76. The incoming velocity may also facilitate the transfer of heat from the reaction with organic lubricants and binders in the “green” parts and the transfer of the resulting reaction byproducts.

In some embodiments, the gas heater 52 conditions the supplied gas from the gas supply 50 to create a conditioned atmosphere 70. The conditioned atmosphere may achieve a predetermined temperature greater than 700 degrees Fahrenheit before it is introduced to the reaction zone. The temperature of the conditioned atmosphere may be between 700 and 1,800-degrees Fahrenheit.

In some embodiments, the thermal processing apparatus may be communicatively connected to a chamber, furnace, or other instruments that may contain an atmosphere distinct from the conditioned atmosphere being supplied to the reaction zone from the plenum. The apparatus may be operatively connected to a chamber, furnace, or other instruments via the second opening 24. In one non-limiting embodiment, the apparatus may be operatively and communicatively connected to another thermal processing furnace 34. An incoming atmosphere 76 may be introduced from the second opening into the reaction zone 20 of the apparatus. The incoming atmosphere and the conditioned atmosphere 70 may each have a velocity into the reaction zone that is sufficient to uniformly mix the incoming atmosphere with the conditioned atmosphere.

In some embodiments, the incoming atmosphere 76 comprises at least one of hydrogen, a mixture of hydrogen and nitrogen, natural gas, dissociated ammonia, an inert gas, an endothermic gas mixture, or an exothermic gas mixture.

In some embodiments, the conditioned atmosphere 70 and the incoming atmosphere 76 are introduced into the reaction zone 20 with sufficient velocities, compositions, and temperatures to react with and expend all the combustibles coming from the incoming atmosphere and the organic vapors generated from the admixed lubricants from the “green” parts. The reaction of the incoming atmosphere, the conditioned atmosphere, and the organic vapors being released from the “green” parts may decompose all harmful hydrocarbon vapors into safe byproducts comprising one or more of nitrogen, hydrogen, oxygen, nitrogen, and water vapor. Therefore, the resulting byproducts are non-harmful emissions that can be vented through the exhaust system 32 communicatively connected to the first opening 22 with no additional treatment steps.

In some embodiments, the parameters of the conditioned atmosphere 70 and incoming atmosphere 76 will be such that all of the organic lubricants and binders in the “green” part are completely removed from the metallurgy part and decomposed into harmless byproducts. The parameters of the conditioned atmosphere and incoming atmosphere within the reaction zone 20 may be highly oxidizing to the organic materials within the “green” parts, but non-oxidizing to the powdered metal or resulting metallic part. One common type of organic binder used to create “green” parts, especially in the creation of iron-based and steel parts, is Ethylene BiSteramide commercially known as AcraWax. AcraWax melts at about 300 degrees Fahrenheit and starts to vaporize at about 500-600 degrees Fahrenheit, slowly first and relatively faster as the “green” part temperature reaches 1000-1200 degrees Fahrenheit. The conditions of the atmosphere within the reaction zone are determined and controlled so that the temperature within the reaction zone is sufficiently high and the atmosphere within the reaction zone is sufficiently oxidizing to ensure that the removal of the organic lubricants or binders occurs as quickly as possible and that the resulting decomposition of the organic lubricants or binders does not leave solid residue within the interstitial spaces of the metallic parts or within the interior of the reaction zone.

In some non-limiting embodiments, the apparatus may be a modular thermal processing apparatus comprising a plurality of heat treatment modules 10. The plurality of heat treatment modules will contain at least a first module 12 and a last module 14. Each of the heat treatment modules will further comprise the following subparts: a reaction zone 20 having a first 22 and second opening 24, a conveyor system 30, an exhaust system 32, a plenum 40, a gas supply 50, a gas heater 52, and a vented barrier 60 comprising a plurality of vents 62.

In the embodiments discussed herein, the modular thermal processing apparatus has a length extending in the direction from the first opening of the first module to the second opening of the last module, a height extending upward from the conveyor system, and a width extending across the apparatus.

In some embodiments, each module's reaction zone 20 forms the primary chamber of the thermal processing apparatus in which metallurgy parts will pass through to achieve the melting, vaporizing, removing, and oxidizing of organic binders and lubricants. The plurality of heat treatment modules 10 may be arranged in series such that each module's reaction zone is operatively connected to the reaction zone of one or more other modules to create a series of interconnected reactions zones with a single conveyor system 30 that transports “green” parts through the successive reaction zones. Each module's reaction zone may have a first opening 22 and a second opening 24 positioned at opposite sides of the reaction zone so that a metallurgy part may be introduced into the reaction zone through the first module's 12 first opening, where it may progress through the reaction zone at a determined rate and exit the reaction zone through the last module's 14 second opening. The modules may be configured so that the first opening of each successive module is operatively connected to the second opening of the proceeding module. In some embodiments, the exterior of the apparatus around the first and second openings may further include flanges, or other methods of connection known to those of ordinary skill in the art, so that the reaction zone of each module may be communicatively connected to the reaction zone of a proceeding or succeeding module's reaction zone. In some embodiments, the second opening of the last module may be communicatively connected to another chamber, instrument, or apparatus. The last module may be communicatively connected to an existing thermal processing furnace 34 to augment or retrofit the capabilities of an existing instrument. The size of the openings of each module may be adjusted to accommodate the introduction of parts of various sizes and to allow for the control of an incoming or outgoing atmosphere. The apparatus may also include an exhaust system 32 that may be communicatively connected to the first opening of the first module. The cross-sectional area of the reaction zones of the modular apparatus may be smaller toward the second opening of the last module and larger toward the first opening of the first module to create a pressure gradient so that the atmosphere within the interconnected reaction zones will flow toward the exhaust system communicatively connected to the first opening of the first module.

The modular thermal processing apparatus may further include a conveyor system 30 that transports a desired material through each module's reaction zone from the first opening to the second opening. In some embodiments, each module has an independent conveyor system. In other embodiments, the modules share a single conveyor system that extends throughout the interconnected plurality of modules and transports the desired material through the series of modules 10. A conveyor system is not intended to be limited to any particular form of a conveyor system and may include various types of conveyor systems or equivalent forms of movement systems that would be recognized by a person of ordinary skill in the art. The conveyor system or systems may be one of but is not limited to: a belt conveyor, a gravity roller conveyor, a chain conveyor, a pusher plate system, a chain driven line conveyor, or other forms of roller systems like roller hearths. The conveyor system or systems may be controlled by the user using systems known to those of ordinary skill in the art to achieve a desired movement rate or multiple movement rates.

In some embodiments, the modular thermal processing apparatus includes a plenum 40 positioned above each module's reaction zone 20. Each module's plenum may be a contained space or duct that is suited for the conditioning of a gaseous atmosphere. Each module's plenum may be an airtight duct with the exception of a vented barrier 60. The plenums, therefore, will contain the introduced gas from the module's gas supply 50 while the conditioned atmosphere 70 builds in pressure and is subsequently directed through the vents in the module's vented barrier. In some embodiments, each module's plenum extends above the module's reaction zone for almost the entire length of the reaction zone: from about the module's first opening 22 to about its second opening 24. In other embodiments, each module's plenum 40 extends across only a fraction of the length of the reaction zone. The plenum may be positioned to extend along at least one side of a module's reaction zone. The position of the plenum in relation to the reaction zone may be different for each module.

In some embodiments, each module's plenum 40 is communicatively connected to a gas supply 50 and a gas heater 52. The gas supply of each module may be a compressor. Each module's gas supply may be a compressed gas tank. While in some embodiments, a module's gas supply may comprise both a compressor and a gas tank. A module's gas supply may use a regulator or other equivalent means of regulating the conditions of the supplied gas. Each module may use a different form of gas supply. In some embodiments, all the modules will use the same type of gas supply. The gas supply and the gas heater may be contained within a module's plenum, while in other embodiments one or both the gas supply and gas heater may be positioned on the exterior of a module's plenum such that they are communicatively connected to the plenum to provide a conditioned atmosphere 70 to the plenum's interior chamber. Each module's gas supply and gas heater condition and introduce an atmosphere to the module's plenum. Each module's gas supply, gas heater, and plenum may be arranged in series so that a gas is supplied from the gas supply to the gas heater, the gas heater conditions the supplied gas, and the conditioned gas is delivered to the plenum to create a conditioned atmosphere within the plenum of controlled composition, pressure, and temperature. As the conditioned atmosphere is introduced into each module's plenum, the pressure builds within the interior chamber of the plenum until the conditioned atmosphere is released through the plurality of vents 62 in the vented barrier 60 and into the module's reaction zone 20.

In some embodiments, the modular thermal processing apparatus contains one or more vented barriers 60, such that a vented barrier is positioned between each module's plenum 40 and each module's reaction zone 20. The vented barrier may be positioned between a module's plenum and reaction zone such that the plenum is positioned above the module's vented barrier and the module's reaction zone is positioned below the vented barrier. The one or more vented barriers are made from a high-temperature plate metal. The high-temperature plate metal may be a heat resistant metal that can sustain large variations in temperature. In one non-limiting embodiment, the high-temperature plate metal may be a steel-containing alloy. However, the high-temperature plate metal may be made of any material known to those of ordinary skill that could maintain its thermal and structural properties in the high-temperature environments of this modular thermal processing apparatus.

In some embodiments, the one or more vented barriers 60 comprise a plurality of vents 62. The plurality of vents may be distributed within the vented barrier so that each vent is spaced uniformly to create a uniform density of vents across the entire length of the vented barrier. The plurality of vents may be arranged so that the density of vents is highest near the first opening 22 of the first module 12 of the reaction zone and progressively lower toward the second opening 24 of the last module 14. The plurality of vents may be distributed as a plurality of linear rows 64 that extends across the width of the apparatus. The number of vents that comprise each of the linear rows of vents may vary based on the rows' position within the apparatus. In one non-limiting embodiment, the plurality of rows may comprise at least four rows of vents and each row may comprise at least six individual vents. Each individual module may be configured such that there are different densities of vents across the module's vented barrier or vented barriers to effectively create multiple sub-zones within the module that may produce different conditions for the introduction of the conditioned atmosphere 70.

In some embodiments, each vent 66 in the plurality of vents 62 is an opening with a rectangular cross-sectional area within the one or more vented barriers. The vents may all have a uniform size to control the pressure conditions of each module's conditioned atmosphere as it flows through each of the vents. The aspect ratio of the cross-sectional area of each vent may be at least 5. In other embodiments, the vents may have triangular, square, ovular, or circular cross-sectional areas.

In some embodiments, the gas supply 50 and the gas heater 52 of each module may be programmed to condition the supplied gas to create a conditioned atmosphere 70 in each module's plenum 40 with a desired flow, temperature, pressure, and chemical composition for thermal processing. Each module's gas supply and the gas heater may be programmed and controlled with an external processor and external monitoring programs known to those of ordinary skill. The gas supply and the gas heater may also be programmed manually via the controls on the individual instruments. Each module's gas supply and the gas heater can be pre-programmed to condition an atmosphere with unchanging conditions throughout the entire thermal processing cycle. Each module's gas supply and the gas heater may also be programmed either before or during the thermal processing cycle to produce and deliver a conditioned atmosphere with adaptive and/or changing conditions throughout the thermal processing cycle. In some embodiments, one or more of the plurality of modules 10 may introduce a conditioned atmosphere with unchanging conditions throughout the thermal processing cycle, while one or more other modules may introduce a conditioned atmosphere with adaptive and/or changing conditions throughout the thermal processing cycle.

In some embodiments, each module's compressed gas supply 50 provides an oxygen-containing gas to create a conditioned atmosphere 70. Each module's supplied gas may be an oxygen-containing gas, having an oxygen content between 2 and 100 percent. The oxygen-containing gas may also be balanced with an inert gas like nitrogen. In another embodiment, each module's supplied gas is comprised of hydrogen. The conditioned atmosphere of each module may be partially comprised of nitrogen, hydrogen, carbon monoxide, methane, water vapor, carbon dioxide, and oxygen. In one non-limiting embodiment, each module's compressed gas supply may provide air to create a conditioned atmosphere. In some embodiments, each module's gas supply may supply the same composition of gas. In other embodiments, each module's gas supply may supply a different composition of gas. In some embodiments, the total combined amount of oxygen entering all the modules' reaction zones 20 within the apparatus is greater than or equal to the stoichiometric amount needed to react with and expend all the combustibles coming from an incoming atmosphere 76 and the organic vapors generated from the admixed lubricants from the “green” parts. Each module's gas supply may provide enough gas to the plenum 40 so that the resulting conditioned atmosphere reaches and is maintained at a predetermined pressure condition within each module's plenum. Each module's gas supply may provide an amount of gas to create a conditioned atmosphere within the reaction zone with adequate pressure and temperature to produce a gas flow through each of the vents 66 at a rate of 3 to 15 miles per hour. The amount of gas being supplied to the plenum may be varied to create adequate flow conditions through the plurality of vents 62. In some embodiments, the amount of gas being supplied into the thermal processing apparatus may be between 50 and 2000 SCFH. The pressure conditions in one module's plenum may vary from the pressure conditions in one or more other modules' plenums. The conditioned atmosphere may be introduced to each module's reaction zone through the plurality of vents at a velocity sufficient to quickly mix and react with the combustibles coming from an incoming atmosphere. The incoming velocity may also facilitate the transfer of heat from the reaction with organic lubricants and binders in the “green” parts and the transfer of the resulting reaction byproducts.

In some embodiments, each module's gas heater 52 conditions the supplied gas from the gas supply 50 to create a conditioned atmosphere 70. The conditioned atmosphere may achieve a predetermined temperature greater than 700 degrees Fahrenheit before it is introduced to each module's reaction zone 20. In one non-limiting embodiment, the temperature of the conditioned atmosphere may be between 700 and 1,800 degrees Fahrenheit.

In some embodiments, the modular thermal processing apparatus may be communicatively connected to a chamber, furnace, or other instruments that may contain an atmosphere distinct from the conditioned atmosphere 70 being supplied to each module's reaction zone from each module's plenum 40. The apparatus may be operatively connected to a chamber, furnace, or other instruments via the second opening 24 of the last module 14. In one non-limiting embodiment, the apparatus may be operatively and communicatively connected to another thermal processing furnace 34. An incoming atmosphere 76 may be introduced through the second opening of the last module into the last module's reaction zone 20. The incoming atmosphere may subsequently progress through the connected modules so that the incoming atmosphere uniformly mixes with the conditioned atmosphere being introduced in each module's reaction zone. The incoming atmosphere and each module's conditioned atmosphere may each have an introduction velocity into any module's reaction zone that is sufficient to uniformly mix the incoming atmosphere with the conditioned atmosphere.

In some embodiments, the incoming atmosphere 76 comprises at least one of hydrogen, a mixture of hydrogen and nitrogen, natural gas, dissociated ammonia, an inert gas, an endothermic gas mixture, or an exothermic gas mixture.

In some embodiments, the conditioned atmosphere 70 from each module and the incoming atmosphere 76 are introduced into each module's reaction zone 20 with sufficient velocities, compositions, and temperatures to react with and expend all the combustibles coming from the incoming atmosphere and the organic vapors generated from the admixed lubricants from the “green” parts. The reaction of the incoming atmosphere, the conditioned atmosphere, and the organic vapors being released from the “green” parts may decompose all harmful hydrocarbon vapors into safe byproducts comprising one or more of nitrogen, hydrogen, oxygen, nitrogen, and water vapor. Therefore, the resulting byproducts are non-harmful emissions that can be vented through the exhaust system 32 communicatively connected to the first opening 22 of the first module 12 with no additional treatment steps.

In some embodiments, the parameters of the collective conditioned atmosphere 70 being introduced within each module and the incoming atmosphere 76 will be such that all of the organic lubricants and binders in the “green” parts are completely removed from the metallic part and decomposed into harmless byproducts. The parameters of the conditioned atmosphere and incoming atmosphere within the reaction zone 20 may be highly oxidizing to the organic materials within the “green” parts, but non-oxidizing to the powdered metal or resulting metallic part. One common type of organic binder used to create “green” parts, especially in the creation of iron-based and steel parts, is Ethylene BiSteramide commercially known as AcraWax.

AcraWax melts at about 300 degrees Fahrenheit and starts to vaporize at about 500-600 degrees Fahrenheit, slowly first and relatively faster as the “green” part temperature reaches 1000-1200 degrees Fahrenheit. In some embodiments, the conditions of the mixed atmosphere within the reaction zone are determined and controlled so that the temperature within the reaction zone is sufficiently high and the mixed atmosphere 74 within the reaction zone is sufficiently oxidizing to ensure that the removal of the organic lubricants or binders occurs as quickly as possible and that the resulting decomposition of the organic lubricants or binders does not leave solid residue within the interstitial spaces of the metallic parts or within the interior of any of the reaction zones.

In some embodiments, the modular thermal processing apparatus contains a plurality of modules 10 of a uniform length. In other embodiments, the modular thermal processing apparatus may contain modules of varying lengths. In one non-limiting embodiment, the first module 12 has a smaller length than any subsequent module. The overall length of any one module is not less than ten percent of the total length of the modular thermal processing apparatus.

In some embodiments, the modular thermal processing apparatus will contain more than one module. The modular thermal processing apparatus may comprise at least three modules.

In some embodiments, the following process may be used. The process comprises a method of treating metallurgy parts containing hydrocarbon-based lubricants, binders, and oils in a thermal processing apparatus. The thermal processing apparatus may comprise a reaction zone 20 having a first 22 and second opening 24 and an exhaust system 32 communicatively connected to the first opening. A conveyor system 30 may also be used to transport a desired material from the first opening to the second opening. A plenum 40 may be positioned above the reaction zone, a gas heater 50 and a gas supply 52 may be communicatively connected to the plenum, and a vented barrier 60 may be positioned between the plenum and the reaction zone. The vented barrier may comprise a plurality of vents 62 arranged such that the density of the vents is highest near the first opening and progressively lower toward the second opening. The gas supply and the gas heater introduce and condition an atmosphere 70 to the plenum, which then is released into the reaction zone through the plurality of vents.

In one embodiment, the process of treating metallurgy parts using a thermal processing apparatus involves the use of a transportation system to transport a desired material through the reaction zone, where the material enters through the first opening and exits through the second opening. The process may use a conveyor system 30 to transport the desired materials through the reaction zone. A conveyor system is not intended to be limited to any particular form of a conveyor system and may include various types of conveyor systems or equivalent forms of movement systems that would be recognized by a person of ordinary skill in the art. The process may use various forms of conveyor systems including, but not limited to, a belt conveyor, a gravity roller conveyor, a chain conveyor, a pusher plate system, a chain driven line conveyor, or other forms of roller systems like roller hearths. The conveyor system may move continuously when transporting a metallurgy part through the thermal processing apparatus. In other embodiments, the conveyor system may employ stops or holding periods in which the metallurgy part is not moving within the thermal processing apparatus. The conveyor system may be controlled by an external processor and a computer program that may be used to program or otherwise dictate the speed of the conveyor system. The conveyor system may also be controlled by equivalent systems known to those of ordinary skill in the art to achieve a desired movement rate or multiple movement rates.

In some embodiments, the process of treating metallurgy parts using a thermal processing apparatus involves conditioning the atmosphere within the plenum to achieve predetermined temperature, flow, and composition conditions optimal for the treatment of the metallurgy parts. The creation of the conditioned atmosphere 70 may be principally achieved through the use of the gas heater 52 and the gas supply 50. In some embodiments, the gas supply may be a compressor. In other embodiments, the gas supply may be a compressed gas tank. The gas supply may comprise both a compressor and a gas tank. The compressed gas supply may use a regulator or other equivalent means of controlling the pressure conditions of the supplied gas. In some embodiments, the gas supply and the gas heater may be contained within the plenum 40, while in other embodiments one or both the gas supply and gas heater may be positioned outside of the plenum such that they are communicatively connected to the plenum to provide a conditioned atmosphere to the plenum's interior chamber. The gas supply, the gas heater, and the plenum may be arranged in series so that the gas is supplied from the gas supply to the gas heater, the gas heater conditions the supplied gas, and the conditioned gas is delivered to the plenum to create a conditioned atmosphere within the plenum of controlled composition, pressure, and temperature.

In some embodiments, the gas supply 50 and the gas heater 52 may be programmed to condition the supplied gas to create a conditioned atmosphere 70 in the plenum with a desired flow, temperature, pressure, and chemical composition for the thermal treatment process. The gas supply and the gas heater may be programmed and controlled with an external processor and external monitoring programs known to those of ordinary skill. The gas supply and the gas heater may also be programmed manually via the controls on the individual instruments. The gas supply and the gas heater may be pre-programmed to condition an atmosphere with unchanging conditions throughout the entire thermal processing cycle. Otherwise, the gas supply and the gas heater may be programmed either before or during the thermal processing cycle to produce and deliver a conditioned atmosphere with adaptive and/or changing conditions throughout the thermal processing cycle.

In some embodiments, the compressed gas supply 50 provides an oxygen-containing gas to create the conditioned atmosphere. The supplied gas may be an oxygen-containing gas having an oxygen content between 2 and 100 percent. The oxygen-containing gas may also be balanced with an inert gas like nitrogen. In another embodiment, the supplied gas is comprised of hydrogen. The conditioned atmosphere 70 may be partially comprised of nitrogen, hydrogen, carbon monoxide, methane, water vapor, carbon dioxide, and oxygen. In one non-limiting embodiment, the compressed gas supply provides air to create a conditioned atmosphere. The concentration of any gas supplied to create the conditioned atmosphere may be highest near the first opening 22 and lowest near the second opening 24. The total combined amount of oxygen entering the reaction zone 20 of the apparatus may be greater than or equal to the stoichiometric amount needed to react with and expend all the combustibles coming from an incoming atmosphere 76 and the organic vapors generated from the admixed lubricants from the “green” parts.

In some embodiments, the gas heater conditions the supplied gas from the gas supply to create a conditioned atmosphere. The conditioned atmosphere may achieve a predetermined temperature greater than 700 degrees Fahrenheit before it is introduced to the reaction zone. In one non-limiting embodiment, the temperature of the conditioned atmosphere may be between 700 and 1,800 degrees Fahrenheit.

In some embodiments, the conditioned atmosphere 70 may then be supplied at a predetermined velocity to the reaction zone 20 through the plurality of vents 62. The thermal processing apparatus may contain a vented barrier 60 that is positioned between the plenum 40 and the reaction zone. The vented barrier may be made from a high-temperature plate metal. In some embodiments, the vented barrier comprises a plurality of vents. The plurality of vents may be distributed so that the density of vents is highest near the first opening 22 of the reaction zone and progressively lower toward the second opening 24. The plurality of vents may be distributed as a plurality of linear rows 64 that extends across the width of the apparatus. The number of vents 66 that comprise each of the linear rows of vents may vary based on the row's position within the apparatus. In one non-limiting embodiment, the plurality of rows may comprise at least four rows of vents and each row may comprise at least six individual vents.

In some embodiments, each vent 66 in the plurality of vents 62 is an opening within the vented barrier 60 with a rectangular cross-sectional area. The vents may all have a uniform size to control the pressure conditions of the conditioned atmosphere 70 as it flows through each of the vents. The aspect ratio of the cross-sectional area of each vent may be at least 5. In other embodiments, the vents may have triangular, square, ovular, or circular cross-sectional areas.

As the conditioned atmosphere 70 is introduced into the plenum 40, the pressure of the supplied gas builds within the interior chamber of the plenum until the conditioned atmosphere is released through the plurality of vents 62 in the vented barrier 60 and into the reaction zone 20. The gas supply 50 may provide enough gas to the plenum so that the resulting conditioned atmosphere reaches and is maintained at a predetermined pressure condition within the plenum. The gas supply may provide an amount of gas to create a conditioned atmosphere within the plenum with adequate pressure and temperature to produce a gas flow through each of the vents 66 at a rate of 3 to 15 miles per hour. The amount of gas being supplied to the plenum may be varied to create adequate pressure conditions to ensure proper gas flow velocities through the plurality of vents 62. In some embodiments, the amount of gas being supplied into the thermal processing apparatus may be between 50 and 2000 SCFH. The conditioned atmosphere may be introduced to the reaction zone through the plurality of vents at a velocity sufficient to quickly mix and react with the combustibles coming from the incoming atmosphere 76.

In some embodiments, the metallurgy parts are transported through the reaction zone via the conveyor system 30 so that the parts are exposed to the conditioned atmosphere 70 within the reaction zone 20. The conditioned atmosphere may be mixed with an incoming atmosphere 76 coming from the second opening 24. In some embodiments, the conditions of the resulting mixed atmosphere 74 are controlled to be sufficiently oxidizing and produce oxidation profiles in the vicinity of the metallurgy parts to remove lubricants and oxidize the desired material. In some embodiments, the desired material is a “green” part. The conditions of the mixed atmosphere within the reaction zone are determined and controlled so that the temperature within the reaction zone is sufficiently high, and the mixed atmosphere within the reaction zone is sufficiently oxidizing, to produce oxidation profiles in the vicinity of the metallurgy parts that ensure that the removal of the organic lubricants or binders occurs as quickly as possible. The conditions of the mixed atmosphere may be controlled so that the resulting decomposition of the organic lubricants or binders does not leave solid residue within the interstitial spaces of the metallurgy parts or within the interior of the reaction zone. The oxidation potential of the resulting mixed atmosphere in the reaction zone may be highest near the first opening 22 and progressively lower toward the second opening 24. The oxidation potential of oxidants in the mixed atmosphere within the reaction zone and in the vicinity of the metallurgy parts may be expressed as the dew point. The dew point within the reaction zone may be continuously decreasing across the length of the reaction zone from the first opening to the second opening. The dew point within the reaction zone may be highest near the first opening and lowest near the second opening. In some non-limiting embodiments, the dew point of the conditioned atmosphere is above 80 degrees Fahrenheit in the vicinity of the first opening and less than 10 degrees Fahrenheit in the vicinity of the second opening. Additionally, the primary oxidant in the mixed atmosphere may be water vapor.

In some embodiments, the oxidant levels and oxidation profile surrounding the metallurgy parts may be controlled by manipulating the following parameters: the velocity of the conditioned atmosphere 70 entering the reaction zone 20 through the plurality of vents 62, the chemical composition of the conditioned atmosphere, the chemical composition of the incoming atmosphere 76 entering from the second opening 24, the temperature of the conditioned atmosphere, the temperature of the incoming atmosphere, the shape and cross-sectional area of each vent 66, the number of vents, the density and spatial distribution of vents within the vented barrier 60, and the amount of hydrocarbon byproducts in the vicinity of the metallurgy parts resulting from the heating of the organic lubricants or binders.

In some embodiments, metallurgy parts may be treated by progressing the desired materials through the reaction zone 20, where the temperature of the metallurgy parts gradually increases from the first opening 22 toward the second opening 24. Additionally, the increasing temperature of the mixed atmosphere 74 in the reaction zone will facilitate the removal of organic lubricants, binders, and oils and the breakdown of the resulting hydro-carbon-based vapors to produce a treated atmosphere 72 within the reaction zone. The interaction of organic lubricants and oils with the conditioned atmosphere generates heat from the oxidation and decomposition of these organic materials. The heat generated from these reactions is often referred to as the thermal head in the vicinity of the part. Like the oxidation potential of the atmosphere, expressed as the dew point, the thermal head is highest near the first opening and progressively decreases toward the second opening. Although the thermal head progressively decreases from the first opening to the second opening, the temperature in the immediate vicinity of the part traveling through the reaction zone from the first opening to the second opening is continuously increasing. In some embodiments, the temperature of the metallurgy parts is approximately room temperature near the first opening and above 1000 degrees Fahrenheit near the second opening.

In some embodiments, the metallurgy parts progress through the reaction zone 20, decomposing and vaporizing the organic oils and binders on and within the metallurgy part so that no physical residue or soot is left within the metallurgy part or within the reaction zone, and then progressing through the second opening 24 of the thermal processing apparatus. The metallurgy parts may be completely free of soot, hydrocarbon materials, or other physical residues from the decomposition of the organic lubricants, oils, and binders as the parts pass through the second opening. Additionally, the metallurgy parts may progress through the second opening of the thermal processing apparatus into a separate apparatus 34 for further thermal processing.

In some embodiments, the removal and vaporization of organic lubricants, binders, and oils and the breakdown of the resulting hydro-carbon-based vapors produce a treated atmosphere 72 within the reaction zone 20. The treated atmosphere may then be vented through an exhaust system 32 communicatively connected to the first opening 22. In some embodiments, the treated atmosphere is free of hydrocarbon and other harmful vapors.

In some embodiments, the following process may be used. The process comprises a method of treating metallurgy parts containing hydrocarbon-based lubricants, binders, and oils in a modular thermal processing apparatus. The modular thermal processing apparatus may comprise a plurality of modules 10, where each module may further comprise: a reaction zone 20 having a first 22 and a second opening 24. Each module may also use a conveyor system 30 to transport a desired material from the first opening of the first module 12 to the second opening of the last module 14. There may also be a plenum 40 positioned above each module's reaction zone, a gas heater 52 and a gas supply 50 communicatively connected to each module's plenum, and a vented barrier 60 between each module's plenum and reaction zone. Each module may have a plenum and a vented barrier separating the module's plenum from the module's reaction zone. A module's vented barrier may comprise a plurality of vents 62 arranged such that the density of the vents is highest near the first opening of the first module and progressively lower toward the second opening of the last module. Each module's gas supply and the gas heater may introduce and condition an atmosphere 70 to the module's plenum, which then is released into the module's reaction zone through the plurality of vents.

In one embodiment, the process of treating metallurgy parts using a modular thermal processing apparatus involves the use of a transportation system to transport a desired material through each module's reaction zone, where the material enters through the module's first opening 22 and exits through the module's second opening 24. The process may use a conveyor system 30 to transport the desired materials through the reaction zone 20. In some embodiments, each module uses a distinct conveyor system. Alternatively, a single conveyor system may be shared by all of the modules and extend through the interconnected modules 10 so the single conveyor system may transport the desired materials from the first opening of the first module 12 to the second opening of the last module 14. A conveyor system is not intended to be limited to any particular form of a conveyor system and may include various types of conveyor systems or equivalent forms of movement systems that would be recognized by a person of ordinary skill in the art. The process may use various forms of conveyor systems including, but not limited to, a belt conveyor, a gravity roller conveyor, a chain conveyor, a pusher plate system, a chain driven line conveyor, or other forms of roller systems like roller hearths. The conveyor system may move continuously when transporting a metallurgy part through the thermal processing apparatus. In other embodiments, the conveyor system may employ stops or holding periods in which the metallurgy part is not moving within the thermal processing apparatus. The conveyor system may be controlled by an external processor and a computer program that may be used to program or otherwise dictate the speed of the conveyor system. The conveyor system may also be controlled by equivalent systems known to those of ordinary skill in the art to achieve a desired movement rate or multiple movement rates.

In some embodiments, the process of treating metallurgy parts using a modular thermal processing apparatus involves conditioning the atmosphere 70 within each module's plenum 40 to achieve predetermined temperature, flow, and composition conditions optimal for the treatment of the metallurgy parts. In some embodiments, the atmosphere conditioned and introduced in each module will be identical. In other embodiments, the atmosphere conditioned and introduced in each module may have different temperature, flow, and composition conditions from the other modules. The creation of each module's conditioned atmosphere may be principally achieved using the module's gas heater 52 and the gas supply 50. In some embodiments, the gas supply may be a compressor. In other embodiments, the gas supply may be a compressed gas tank. Additionally, the gas supply may comprise both a compressor and a gas tank. The compressed gas supply may use a regulator or other equivalent means of controlling the pressure conditions of the supplied gas. The gas supply and the gas heater may be contained within each module's plenum, while in other embodiments one or both the gas supply and gas heater may be positioned outside of each module's plenum, such that they are communicatively connected to each module's plenum to provide a conditioned atmosphere to the plenum's interior chamber. Each module's gas supply, the gas heater, and the plenum may be arranged in series so that the gas is supplied from the gas supply to the gas heater, the gas heater conditions the supplied gas, and the conditioned gas is delivered to the plenum to create a conditioned atmosphere within each module's plenum of controlled composition, pressure, and temperature.

In some embodiments, each module's gas supply 50 and gas heater 52 may be programmed to condition the supplied gas to create a conditioned atmosphere 70 in each module's plenum 40 with a desired flow, temperature, pressure, and chemical composition for the thermal treatment process. Each module's gas supply and the gas heater may be programmed or controlled with an external processor and external monitoring programs known to those of ordinary skill. Each module's gas supply and gas heater may also be programmed manually via the controls on the individual instruments. Each module's gas supply and gas heater may be pre-programmed to condition an atmosphere with unchanging conditions throughout the entire thermal processing cycle. In other embodiments, each module's gas supply and gas heater may be programmed, either before or during the thermal processing cycle, to produce and deliver a conditioned atmosphere with adaptive and/or changing conditions throughout the thermal processing cycle.

In some embodiments, each module's compressed gas supply 50 provides an oxygen-containing gas to create each module's conditioned atmosphere 70. The supplied gas may be an oxygen-containing gas having an oxygen content between 2 and 100 percent. The oxygen-containing gas may also be balanced with an inert gas like nitrogen. In another embodiment, the supplied gas is comprised of hydrogen. In other embodiments, each module's conditioned atmosphere is partially comprised of nitrogen, hydrogen, carbon monoxide, methane, water vapor, carbon dioxide, and oxygen. In one non-limiting embodiment, each module's compressed gas supply provides air to create a conditioned atmosphere. In some embodiments, the concentration of any gas supplied to create a conditioned atmosphere is highest toward the first opening 22 of the first module 12 and lowest toward the second opening 24 of the last module 14. In some embodiments, the total combined amount of oxygen entering all the modules' reaction zones 10 within the apparatus is greater than or equal to the stoichiometric amount needed to react with and expend all the combustibles coming from an incoming atmosphere 76 and the organic vapors generated from the admixed lubricants from the “green” parts.

In some embodiments, each module's gas heater 52 conditions the supplied gas from each module's gas supply 50 to create a conditioned atmosphere 70. The conditioned atmosphere may achieve a predetermined temperature greater than 700 degrees Fahrenheit before it is introduced to each module's reaction zone 20. In one non-limiting embodiment, the temperature of the conditioned atmosphere may be between 700 and 1,800 degrees Fahrenheit.

In some embodiments, each module's conditioned atmosphere 70 may then be supplied at a predetermined velocity to each module's reaction zone 20 through the plurality of vents 62. In some embodiments, the modular thermal processing apparatus contains one or more vented barriers 60 that are positioned between each module's plenum 40 and each module's reaction zone. In some embodiments, each module's vented barrier is made from a high-temperature plate metal. In some embodiments, each module's vented barrier comprises a plurality of vents. The plurality of vents may be distributed so that the density of vents is highest toward the first opening 22 of the first module 12 of the reaction zone and progressively lower toward the second opening 24 of the last module 14. The plurality of vents may be distributed as a plurality of linear rows 64 that extends across the width of the apparatus. The number of vents 66 that comprise each of the linear rows of vents may vary based on the rows' position within the apparatus. In one non-limiting embodiment, the plurality of rows may comprise at least four rows of vents, and each row may comprise at least six individual vents.

In some embodiments, each vent 66 in the plurality of vents 62 is an opening within the vented barrier 60 with a rectangular cross-sectional area. The vents may all have a uniform size to control the pressure conditions of each module's conditioned atmosphere 70 as it flows through each of the vents. In some embodiments, the aspect ratio of the cross-sectional area of each vent is at least 5. In other embodiments, the vents may have triangular, square, ovular, or circular cross-sectional areas.

As the conditioned atmosphere 70 is introduced into each module's plenum 40, the pressure of the supplied gas builds within the interior chamber of the plenum until the conditioned atmosphere is released through the plurality of vents 62 in the vented barrier 60 into each module's reaction zone 20. In some embodiments, each module's gas supply 50 may provide enough gas to the plenum so that the resulting conditioned atmosphere reaches and is maintained at a predetermined pressure condition within the plenum. In some embodiments, each module's gas supply provides an amount of gas necessary to create a conditioned atmosphere within the plenum with adequate pressure and temperature to produce a gas flow through each of the vents 66 at a rate of 3 to 15 miles per hour. The amount of gas being supplied to each module's plenum may be varied to create adequate pressure conditions to ensure proper gas flow velocities through the plurality of vents. In some embodiments, the amount of gas supplied to each of the modules' plenums will be uniform. In other embodiments, the amount of gas supplied to each of the modules' plenums will be varied to create different conditions in each module's plenum. In some embodiments, the amount of gas being supplied into the thermal processing apparatus may be between 50 and 2000 SCFH. Each module's conditioned atmosphere may be introduced to the module's reaction zone through the plurality of vents at a velocity sufficient to quickly mix and react with the combustibles coming from the incoming atmosphere 76.

In some embodiments, the metallurgy parts are transported through the successive and interconnected reaction zones 10 via a conveyor system 30 so that the parts are exposed to the conditioned atmosphere 70 within the modules' reaction zones 20. In some embodiments, the conditioned atmospheres introduced to each module are mixed with an incoming atmosphere 76 coming from the second opening 24 of the last module 14. In some embodiments, the conditioned atmospheres leaving each module's plenum 40 and the incoming atmosphere entering from the second opening of the last module mix within the interconnected reaction zones to create a mixed atmosphere 74. In some embodiments, the conditions of the resulting mixed, conditioned atmosphere are controlled to sufficiently oxidize and produce oxidation profiles in the vicinity of the metallurgy parts to delube and oxidize a desired material. In some embodiments, the desired material is a “green” part. In some embodiments, the conditions of the mixed atmosphere within the interconnected reaction zones are determined and controlled so that the temperature within each module's reaction zone is sufficiently high, and the conditioned atmosphere within each module's reaction zone is sufficiently oxidizing, to produce an oxidation profile in the vicinity of the metallurgy parts that ensures that the removal of organic lubricants and binders occurs as quickly as possible. In some embodiments, the conditions of the mixed atmosphere are controlled so that the desired decomposition of organic lubricants and binders does not leave solid residue within the interstitial spaces of the metallurgy parts or within the interior of any of the reaction zones. In some embodiments, the oxidation potential of the conditioned atmosphere in all of the modules' reaction zones is highest near the first opening 22 of the first module 12 and progressively lower toward the second opening 24 of the last module 14. The oxidation potential of oxidants in the conditioned atmosphere within the modules' reaction zones and in the vicinity of the metallurgy parts may be expressed as the dew point. In some embodiments, the dew point within the reaction zones is continuously decreasing across the length of the apparatus from the first opening of the first module to the second opening of the last module. In some embodiments, the dew point within the interconnected reaction zones is highest toward the first opening of the first module and lowest toward the second opening of the last module. In some non-limiting embodiments, the dew point of the conditioned atmosphere is above 80 degrees Fahrenheit in the vicinity of the first opening of the first module and less than 10 degrees Fahrenheit in the vicinity of the second opening of the last module. In some embodiments, the primary oxidant in the conditioned atmosphere is water vapor.

In some embodiments, the oxidant levels and oxidation profile surrounding the metallurgy parts may be controlled by manipulating the following parameters: the velocity of the conditioned atmosphere 70 entering each module's reaction zone 20 through the plurality of vents 62, the chemical composition of the supplied gas in each module, the chemical composition of the incoming atmosphere 76 entering from the second opening 24 of the last module 14, the temperature of each module's conditioned atmosphere, the temperature of the incoming atmosphere, the shape and cross-sectional area of each vent 66, the number of vents, the density and spatial distribution of vents within each module's vented barrier 60, and the amount of hydrocarbon byproducts in the vicinity of the metallurgy parts resulting from the heating of the organic lubricants or binders.

In some embodiments, metallurgy parts may be treated by progressing the desired materials through the modules' reaction zones 20, where the temperature of the metallurgy parts gradually increases from the first opening 22 of the first module 12 toward the second opening 24 of the last module 14. Additionally, the increasing temperature of the atmosphere in the reaction zones will facilitate the removal of organic lubricants, binders, and oils and the breakdown of the resulting hydro-carbon-based vapors to produce a treated atmosphere 72 within the interconnected reaction zones. The interaction of organic lubricants and oils with the mixed atmosphere 74 generates heat from the oxidation and decomposition of these organic materials. The heat generated from these reactions is often referred to as the thermal head in the vicinity of the part. Like the oxidation potential of the atmosphere, expressed as the dew point, the thermal head is highest near the first opening of the first module and progressively decreases toward the second opening of the last module. Although the thermal head progressively decreases from the first opening of the first module to the second opening of the last module, the temperature in the immediate vicinity of the part traveling through the modules' interconnected reaction zones from the first opening of the first module to the second opening of the last module is continuously increasing. In some embodiments, the temperature of the metallurgy parts is approximately room temperature near the first opening of the first module and above 1000 degrees Fahrenheit near the second opening of the last module.

In some embodiments, the metallurgy parts progress through the interconnected reaction zones 20, decomposing and vaporizing the organic oils and binders on and within the metallurgy part so that no physical residue or soot is left within the metallurgy part or within any of the reaction zones, and then progressing through the second opening 24 of the last module 14 of the thermal processing apparatus. In some embodiments, the metallurgy parts are completely free of soot, hydrocarbon materials, or other physical residues from the decomposition of the organic lubricants, oils, and binders as the parts pass through the second opening of the last module. In some non-limiting embodiments, the metallurgy parts may progress through the second opening of the last module of the thermal processing apparatus into a separate apparatus 34 for further thermal processing.

In some embodiments, the removal and vaporization of organic lubricants, binders, and oils and the breakdown of the resulting hydro-carbon-based vapors produce a treated atmosphere 72 within the modules' reaction zones 20. The treated atmosphere may then be vented through an exhaust system 32 communicatively connected to the first opening 22 of the first module 12. In some embodiments, the treated atmosphere is free of hydrocarbon and other harmful vapors.

### EXAMPLES

### Example 1

Case A: 24-inch-wide belt furnace sintering 266 lb per hour of steel parts with 0.75% by weight of Acrawax lubricant (about 2 lb per hour) using N2 (1250 CFH)+H2 (125 CFH) coming from the Sintering section at 1300 F. Air injected into the plenum is 960 CFH, and pre-heated to 1100 F before being introduced into the reaction zone of the thermal processing apparatus through 160 vents, each vent being 0.8″ long and 0.08.″ The 160 vents are divided into 12 rows along the length of the thermal processing apparatus, which in this example is 3 feet long and is retrofitted to an existing sintering furnace.

The calculations below show the thermodynamically calculated composition of the reaction products in each of the reaction zones and their constituent sub-zones, the thermal head in MBtu and Temperature values in F, and the dew point within the thermal processing apparatus.

Calculations for Thermal Head (Heat Generated from the reactions and levels of Oxidants along the length of the apparatus used in Example Case A.
a. Thermal Head—the total amount of energy generated in the thermal processing apparatus is 75,960 Btu (about 22.3 KwH). It is well distributed across the length of the apparatus. It generated 22.3 KWH/266 lb=0.084 Kw per lb of green parts.
b. The oxidation potential (expressed as a dew point) is continuously decreasing from high of 105.5 F toward the first opening of the thermal processing apparatus down to 64.3 F toward the second opening the 30-inch-long reaction zone.
c. The atmosphere composition throughout the length of the reaction zone is highly oxidizing. The oxidation potential around the “green” parts begins high and decreases as parts travel through the length of the reaction zone.
d. The treated atmosphere composition exiting from the first opening of the thermal processing apparatus is essentially N2, CO2, H2O and O2. There are no harmful hydrocarbon emissions and no combustible gasses like H2 and CO.
e. There is no physical residue like soot left in the reaction zone of the thermal processing apparatus.
f. The temperature in the vicinity of “green” parts, as measured by an exposed thermocouple, is about 600 F as it reaches the end of the reaction zone and exits through the second opening.

Case B: Demonstrates the same thermal processing apparatus as in Case A, but the apparatus is now thermally treating 533 lb per hour of steel parts prepared with the same weight percentage of Acrawax lubricant. The corresponding calculations show the byproducts, temperature and thermal head profiles within the reaction zone:

Calculations in Case B show the same trends as in Case A, but the magnitudes are significantly different: the energy generated if 109,900 Btu (32.2 Kw)—significantly higher to handle twice the amount of lubricant when compared to Case A while using the same thermal processing apparatus.

Not included here, but simply changing the velocity of the introduction of the conditioned atmosphere, the temperature of the conditioned atmosphere, and the flow conditions of the incoming atmosphere can create the requisite temperature and oxidation profiles for the thermal treatment of various metallurgy parts while producing no soot and no harmful emissions.

### Example 2

Case A: 18-inch-wide thermal processing apparatus currently treating 70 lb per hour of steel with 0.80% by weight of Acrawax lubricant (about 0.56 lb per hour) using an incoming atmosphere [N2 (1200 CFH)+H2 (300 CFH)] coming from a thermal processing furnace at 1900 F. Supplied air is maintained at 1200 CFH and conditioned to 1100 F before being injected into three interconnected reaction zones from each module's plenum. Module III is the last module, and Module I is the first module. Module II is in the middle. Modules III, II, and I are 1½ feet, 3 feet and 1½ feet in length respectively. The total length of the apparatus is 6 feet. There are a total of 12 sub-zones—3 in Module III, 6 in Module II, and 3 in Module I. Each zone has multiple vents, somewhat similar to example 1. Pre-heated air distribution in each module is 150 CFH, 450 CFH, and 600 CFH.

The calculations below show the calculated thermal head and oxidants values related to Example 2.

Case A: Like Example 1, the trends in temperature and atmosphere composition profiles are similar but different to suit the production requirements mentioned in the example for this thermal processing furnace. The total heat liberated from the reactions in the thermal processing apparatus is 104,910 Btu (30.7 Kw).

Note also that H2/H2O ration in the first few sub-zones is high enough to reduce the oxides on metallic iron particles so that relatively clean parts can enter the thermal processing furnace for better sintering or bonding between the metallic particles within the entire part.

Case B: Same as Case A in Example 2, except the sintering production rate is increased in the same furnace to double the rate of Case A (i.e. from 70 to 140 lb/hr).

Below are the calculated values for Example 2 Case B:

Case B features the same conditions of the incoming atmosphere and the conditioned atmosphere introduced into the 3 modules as described in Case A. Case B can allow the double production rate without solid carbon “soot” or harmful emissions as in the lower production rate Case A. The energy liberated in case B is higher: 115,130 Btu (33.7 Kw).

Not shown here, but one could reduce the amount of H2 from the current 300 CFH to 200 CFH and still acceptable results (i.e higher throughput with no “soot” and harmful emissions but ⅓rd less H2).

While preferred embodiments of the present invention have been shown and described herein, it will be obvious to those skilled in the art that such embodiments are provided by way of example only. Numerous variations, changes, and substitutions will now occur to those skilled in the art without departing from the invention. It should be understood that various alternatives to the embodiments of the invention described herein may be employed in practicing the invention. It is intended that the following claims define the scope of the invention and that methods and structures within the scope of these claims and their equivalents be covered thereby.

What is claimed is:

1. A method of treating metallurgy parts containing hydrocarbon-based lubricants, binders, and oils in a thermal processing apparatus, the thermal processing apparatus comprising a reaction zone having a first and second opening, an exhaust system communicatively connected to the first opening, a conveyor system that transports a desired material from the first opening to the second opening; a plenum positioned above the reaction zone, a gas heater and a gas supply communicatively connected to the plenum, and a vented barrier between the plenum and the reaction zone, wherein the vented barrier comprises a plurality of vents arranged such that the density of the vents is highest near the first opening and progressively lower toward the second opening, wherein the gas supply and the gas heater condition and introduce an atmosphere to the plenum that is released into said reaction zone through the plurality of vents, the method comprising the steps of:
introducing metallurgy parts into the thermal processing apparatus via the conveyor system;
transporting metallurgy parts through the first opening towards the second opening;
conditioning the atmosphere within the plenum to achieve predetermined temperature, flow, and composition conditions optimal for the treatment of the metallurgy parts;
supplying the conditioned atmosphere at a predetermined velocity to the reaction zone through the plurality of vents;
exposing the metallurgy parts to the conditioned atmosphere within the reaction zone, wherein the oxidation potential of the conditioned atmosphere is highest near the first opening and progressively lower toward the second opening;
progressing the metallurgy parts through the reaction zone such that the temperature of the metallurgy parts gradually increases from the first opening toward the second opening in order to remove and vaporize lubricants, binders, and oils and break down the resulting hydro-carbon-based vapors to produce a treated atmosphere within the reaction zone;
transporting the heated metallurgy parts through the second opening of the thermal processing apparatus; and
venting the treated atmosphere through the exhaust system communicatively connected to the first opening.

2. The method of claim 1, further comprising supplying conditioned atmosphere to the reaction zone through each vent at a rate of 3 to 15 miles per hour.

3. The method of claim 1, further comprising supplying conditioned atmosphere to each reaction zone through the plurality of vents at a temperature of between 700 and 1,800-degrees Fahrenheit.

4. The method of claim 1, wherein the dew point of the conditioned atmosphere is highest near the first opening and lowest near the second opening.

5. The method of claim 1, wherein the dew point of the conditioned atmosphere is above 80 degrees Fahrenheit near the first opening and less than 10 degrees Fahrenheit near the second opening.

6. The method of claim 1, wherein the conditioned atmosphere is partially comprised of water vapor, carbon dioxide, and oxygen, the combined concentration of which is the highest near the first opening and lowest near the second opening.

7. The method of claim 1, wherein the conditioned atmosphere is comprised of hydrogen, the concentration of which is the lowest near the first opening and highest near the second opening.

8. The method of claim 1, wherein the temperature of the metallurgy parts is approximately room temperature near the first opening and above 1000 degrees Fahrenheit near the second opening.

9. The method of claim 1, further comprising metallurgy parts that are essentially free of any soot, hydrocarbon material, or oxidation upon passing through the second opening.

10. The method of claim 1, wherein the treated atmosphere is free of hydrocarbon vapors.

11. A method of treating metallurgy parts containing hydrocarbon-based lubricants, binders, and oils in a modular thermal processing apparatus, the modular thermal processing apparatus comprising at least a first module and a last module, an exhaust system communicatively connected to the first opening of the first module, each module comprising a reaction zone having a first and second opening, a conveyor system that transports a desired material from the first opening of the first module to the second opening of the last module; and a plenum positioned above the reaction zone of each module, a gas heater and a gas supply communicatively connected to the plenum, and a vented barrier between the plenum and the reaction zone of each module wherein the vented barrier comprises a plurality of vents arranged such that the density of the vents is highest in the first module and progressively lower toward the last module, wherein the gas supply and the gas heater introduce and condition an atmosphere to the plenum that is released into said reaction zone through the plurality of vents, the method comprising the steps of:
introducing metallurgy parts into the modular thermal processing apparatus via the conveyor system;
transporting metallurgy parts through the first opening of the first module towards the second opening of the last module;
conditioning the atmosphere within each module's plenum to achieve predetermined flow, temperature and composition conditions optimal for the treatment of the metallurgy parts;
supplying the conditioned atmosphere at a predetermined velocity to each reaction zone through that reaction zone's plurality of vents;
exposing the metallurgy parts to the conditioned atmosphere within each reaction zone, wherein the oxidation potential of the conditioned atmosphere is highest near the first opening of the first module and progressively lower toward the second opening of the last module;
progressing the metallurgy parts through the reaction zones such that the temperature of the metallurgy parts gradually increases from the first opening of the first module toward the second opening of the last module in order to remove lubricants, binders, and oils and break down the resulting hydro-carbon-based vapors to produce a treated atmosphere within the reaction zones;
transporting the heated metallurgy parts through the second opening of the last module of the thermal processing apparatus; and
venting the treated atmosphere through the exhaust system communicatively connected to the first opening of the first module.

12. The method of claim 11, further comprising supplying conditioned atmosphere to each module's reaction zone through each vent at a rate of 3 to 15 miles per hour.

13. The method of claim 11, further comprising supplying conditioned atmosphere to each module's reaction zone through the plurality of vents at a temperature of between 700- and 1,800-degrees Fahrenheit.

14. The method of claim 11, wherein the conditioned atmosphere supplied to each module has different pre-determined conditions.

15. The method of claim 11, wherein the dew point of the conditioned atmosphere is highest near the first opening of the first module and lowest near the second opening of the last module.

16. The method of claim 11, wherein the dew point of the conditioned atmosphere is above 80 degrees Fahrenheit near the first opening of the first module and less than 10 degrees Fahrenheit near the second opening of the last module.

17. The method of claim 11, wherein the conditioned atmosphere is partially comprised of water vapor, carbon dioxide, and oxygen, the combined concentration of which is the highest near the first opening of the first module and lowest near the second opening of the last module.

18. The method of claim 11, wherein the conditioned atmosphere is comprised of hydrogen, the concentration of which is the lowest near the first opening of the first module and highest near the second opening of the last module.

19. The method of claim 11, wherein the temperature of the metallurgy parts is approximately room temperature near the first opening of the first module and above 1000 degrees Fahrenheit near the second opening of the last module.

20. The method of claim 11, further comprising metallurgy parts that are essentially free of any soot, hydrocarbon material, or oxidation upon passing through the second opening of the last module.

21. The method of claim 11, wherein the treated atmosphere is free of hydrocarbon vapors.
